(19) United States
(12) Patent Application Publication
(10) Pub. No.: US 2026/0243519 A1
(43) Pub. Date: Aug. 20, 2026

(54) HEAT SPREADER

(71) Applicant: Conflux Technology Pty Ltd, Waurn Ponds, Victoria (AU)

(72) Inventors: Jason Velardo, Grovedale, Victoria (AU); Michael Fuller, Grovedale, Victoria (AU); Brandon Louey, Grovedale, Victoria (AU)

(73) Assignee: Conflux Technology Pty Ltd, Waurn Ponds, Victoria (AU)

(21) Appl. No.: 19/160,602

(22) PCT Filed: Mar. 6, 2024
(86) PCT No.: PCT/AU2024/050182

§ 371 Date: Aug. 28, 2025

(30) Foreign Application Priority Data
Mar. 8, 2023 (AU) 2023900637

(51) Int. Cl. F28D 15/02; B33Y 10/00; F28D 15/04; F28D 21/00; F28F 3/04; H05K 7/20

(52) U.S. Cl. CPC F28D 15/0266; F28D 15/04; F28F 3/04; B33Y 10/00; F28D 2021/0029; H05K 7/20445

(57) ABSTRACT

A heat spreader, comprising: a body having a first surface, a second surface and an interior space therebetween, with heat being transferred from the first surface to the second surface by migration of vapourised working fluid through the space; and a porous member that is integrally formed with the body that extends around the space and provides a passageway for returning condensed working fluid towards the first surface.

### TECHNICAL FIELD

The invention is directed broadly towards a heat dissipation device. In particular, there is provided an integrally formed two-phase heat spreader and a heat exchanger incorporating said heat spreader.

### BACKGROUND

Electronic devices such as computers and mobile telephones generate significant amounts of heat that must be dissipated to the surroundings. The demand for every increasing levels of processing power and performance within a small form factor is resulting in systems and devices that generate more heat than ever before. When internal components such as microprocessors are exposed to high localised temperatures, their performance and operational life can be severely compromised. Prolonged operation in such conditions may ultimately lead to part failure.

Accordingly, to maintain device performance and reliability, it is important for heat generated by electronic devices to be transported away from critical components, and transferred into the ambient environment. Heat dissipation devices fundamentally assist this cooling process, dissipating heat through combinations of conduction, convection, and radiation. Broadly speaking, heat dissipation devices can be categorised into one of two categories: heat spreaders and exchangers (also known as heat sinks). The primary difference between a heat spreader and a heat exchanger lies in their function-a heat spreader is used to reduce heat flux (moving heat from a concentrated heat source to a heat exchanger having a comparatively larger surface area) whereas a heat exchanger is used to rapidly transfer heat from the electronic device to a surrounding fluid such as atmospheric air.

Vapour chambers are an example of a ‘two-phase’ heat spreader that is used in consumer electronics. In general terms, a vapour chamber is a slender hollow plate-like structure that comprises a sealed volume that contains a prescribed amount of working fluid. When a heat source—such as an electronic component—located on a ‘hot’ or ‘evaporator’ side of the chamber generates a concentrated heat, the fluid within the chamber vapourises and is propelled towards and distributed across an opposing ‘cold’ or ‘condenser’ side of the chamber by pressure difference. On the ‘cold’ side, the fluid is condensed, with its latent heat being rejected to an adjacent external heat exchanger (typically a finned heat sink). The condensed fluid is then pumped by capillary action along a wick structure back to the ‘hot’ side of the vapour chamber. Vapour chambers operate on a similar principal to heat pipes, with a primary difference being that a heat pipe transfers heat in one dimension only, whereas a vapour chamber spreads head across two dimensions.

As a closed-loop system, vapour chambers operate continuously and passively, providing significantly improved effective thermal conductivity (i.e. a reduced thermal resistance) than solid materials, resulting in improved heat spreading performance relative to solid metal and carbon-based thermal spreaders. This being said, however, the effective cooling capacity of the electronic device itself is at least partly dependent on the quality of interface between the vapour chamber and the external heat exchanger, to ensure the heat is efficiently transferred from the ‘cold’ side of the vapour chamber to said heat exchanger.

In order to operate efficiently, the chamber within a vapour chamber must be air-tight. The requirement for a hermetically sealed fluid chamber poses many challenges to the manufacture of vapour chambers, leading to relatively high costs compared to other forms of thermal spreader. Existing vapour chambers are typically fabricated from several discrete components that are assembled together over a series of complex and often tedious steps. For example, it is typical for a vapour chamber to be formed from a pair of precision engineered metal plates that are then sealed together, with a wick structure being bonded to an internal face of one of said plates prior to the sealing process. As the vapour chamber must be vacuum tight, there is little margin for error in the machining and joining of these components, demanding high tolerance levels for the mating metal plates. These high tolerance levels effectively limit the geometry of existing vapour chambers to substantially planar hollow plates. Such flat plate designs limit the ability of heat chambers to be installed within confined spaces, and are a limiting factor in the footprint and internal geometry of modern electronic devices.

Within this context, there is a need for an improved heat spreader or to at least provide the public with a useful choice. The present invention was conceived with these shortcomings in mind.

### SUMMARY

In a first aspect, the invention provides a heat spreader, comprising: a body having a first surface, a second surface and an interior space therebetween, with heat being transferred from the first surface to the second surface by migration of vapourised working fluid through the space; and a porous member that is integrally formed with the body that extends around the space and provides a passageway for returning condensed working fluid towards the first surface.

The body may be a plate body having a substantially constant cross section, with heat being transferred across a thickness thereof between the first and second surfaces.

In some embodiments, the first surface may be shaped to conform to an external geometry of a heat source. The first surface may be curved across each of a length and width thereof. Additionally or alternatively, the second surface may be shaped to conform to an external geometry of a heat sink. The second surface may be curved across each of a length and width thereof.

The space may be under vacuum. A reinforcement structure may be provided within the space that supports the first and second surfaces in a spaced relationship, wherein the reinforcement structure is integrally formed with the body.

In some embodiments, a porosity of the porous member may be tunable in accordance with heat dissipation requirements of the heat spreader. The porosity of the porous member may vary along a length of the passageway.

In a second aspect, the invention provides a method manufacturing a heat spreader as described herein, the method including simultaneously forming the body and the porous member through an additive manufacturing process.

In a third aspect, the invention provides a heat exchanger comprising a base and a plurality of fins in thermal communication therewith, wherein the base is provided in the form of a heat spreader as described herein.

The plurality of fins may be integrally formed with the base. The plurality of fins may be provided in a stacked arrangement, with each fin extending substantially parallel to the base.

In some embodiments, the heat exchanger may further comprise at least one heat transfer member integrally formed with the base that is configured to communicate heat from the base to the plurality of fins. The heat transfer member may extend substantially perpendicular to the base through the plurality of fins to thereby distribute heat substantially evenly thereacross. The heat transfer member may be formed in accordance with the heat spreader as described herein. The space and porous member of the heat transfer member may be in fluid communication, respectively, with the space and porous member of the base.

Each of the plurality of fins may be a hollow fin that is formed in accordance with the heat spreader as described herein. The space and porous member of each of the plurality of fins may be in fluid communication, respectively, with the space and porous member of the base.

### BRIEF DESCRIPTION OF THE DRAWINGS

The invention will now be described, by way of non-limiting example only, with reference to the accompanying drawings, in which:

FIG. 1 is a perspective view of a heat spreader according to an embodiment of the invention, the heat spreader comprising a body having a first external surface for absorbing heat and an opposing second external surface for releasing heat;

FIG. 2 is a side view of the heat spreader of FIG. 1, showing a curved geometry of the first and second external surface along respective lengths and across a widths thereof;

FIG. 3 is a sectional view of the heat spreader along the line B-B of FIG. 2, illustrating an internal space thereof located between the first and second surfaces;

FIG. 4 is a sectional view of the heat spreader along the line A-A of FIG. 1, schematically illustrating heat transfer across the heat spreader;

FIG. 5 is a perspective view of a heat exchanger according to an embodiment of the invention, the heat exchanger comprising a base and a plurality of fins in thermal communication therewith;

FIG. 6 is a sectional view along the line C-C of FIG. 5, showing a heat transfer member extending from the base, through the plurality of fins;

FIG. 7 is a cut-away view of the heat exchanger of FIG. 5, schematically illustrating heat transfer across the heat exchanger;

FIG. 8 is an enlarged view of the encircled region D of FIG. 7, schematically illustrating fluid communication of working fluid between the base and the heat transfer member;

FIG. 9 is a cut-away perspective view of a heat exchanger according to another embodiment of the invention;

FIG. 10 is an enlarged view of the encircled region E of FIG. 9, schematically illustrating fluid communication of working fluid between the base, heat transfer member and fins thereof;

FIG. 11 is a cut-away perspective view of a heat exchanger according to another embodiment of the invention; and

FIG. 12 is an enlarged view of the encircled region F of FIG. 9, schematically illustrating fluid communication of working fluid between the base and heat transfer member.

### DETAILED DESCRIPTION

In the following detailed description, reference is made to accompanying drawings which form a part of the detailed description. It will be readily understood that the aspects of the present disclosure, as generally described herein and illustrated in the drawings may be arranged, substituted, combined, separated and designed in a wide variety of different configurations, all of which are contemplated in this disclosure.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, a limited number of the example methods and materials are described herein.

In general terms, the heat spreader unit 10 shown in the Figures is provided in the form of a vapour chamber. The vapour chamber comprises a body 12 having a first surface 14 and an opposing second surface 16. The body 12 includes an interior space or chamber 18 that is disposed between the first and second surfaces 14, 16. A porous member 20 extends around a periphery of the space 18 and provides a passageway for a working fluid.

In operation, application of a high flux (i.e. concentrated) heat source to the first surface 14 causes working fluid within the passageway 20 proximate the first surface 14 to evaporate into the space 18 and migrate towards the second surface 16. The vaporous working fluid then condenses into the passageway 20 proximate the second surface 16, releasing its latent heat across the second surface 16. With the concentrated heat that is applied to the first surface 14 being spread substantially evenly across a surface area of second surface 16, a high heat flux is reduced to a lower heat flux for dissipation. The working fluid within the passageway 20 is then returned towards the first surface 14 by capillary action, so that the cycle can repeat.

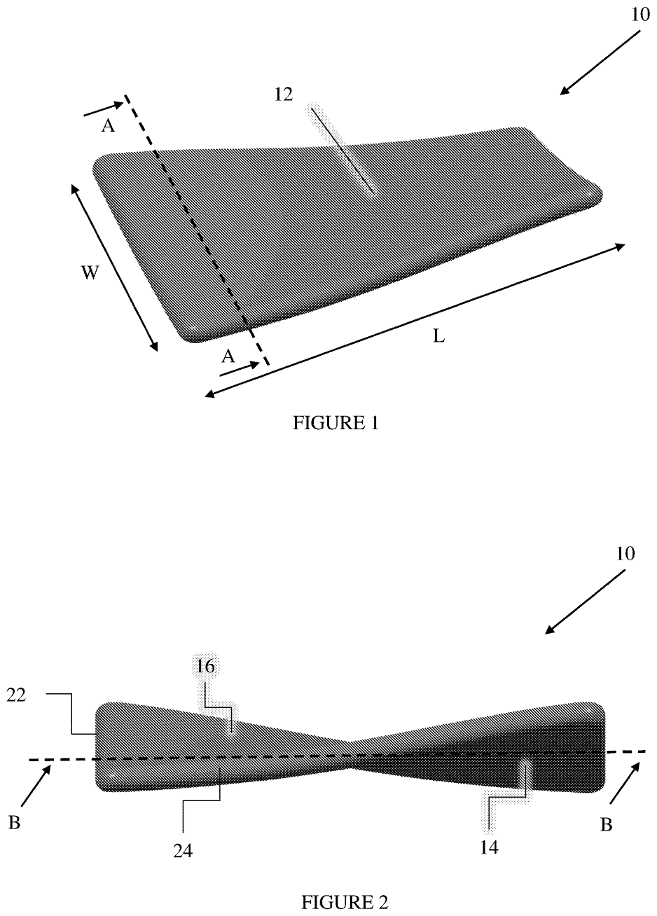

With particular reference to FIGS. 1 to 4, the body 12 of the heat spreader unit 10 is a plate-like body, with the first and second surfaces 14, 16 providing upper and lower walls respectively thereof. The body 12 extends longitudinally along a length L between opposing end walls 22 and laterally in width W between opposing side walls 24. The body 12 is a slender body, having a substantially constant thickness T that is comparatively small with respect to the length L and width W thereof. Notably, the body 12 may be formed as a substantially unitary body, with end walls 22 and/or side walls 24 being curved walls or otherwise smoothly blending with the upper and lower walls 14, 16 to provide a substantially continuous outer surface. For example, the curved end and side walls 22, 24 of the body 12 best shown in FIGS. 1 and 2 reduce sharp edges on the body 12, where such sharp edges/joins would otherwise represent structural weak points in the body 12. Accordingly, it is understood that the body 12 of the heat spreader unit 10 is a particularly resilient body.

As shown, the first and second surfaces are generally rectangular in shape, having a constant width W. It is understood, however, that the surfaces 14, 16 (and thus the body 12 formed in part thereby) need not be rectangular. That is, the first and second surfaces 14, 16 may not be of substantially constant width W. For example, the surfaces 14, 16 may have a width W that tapers between the end walls 22. Such tapering may enable the body 12 to conform to a geometry of adjacent components, minimizing the footprint of the heat spreader unit 10 and thus allowing for the heat spreader 10 to be installed within confined internal enclosures.

Best shown in FIG. 2, each of the first and second surfaces 14, 16 are contoured surfaces. What is meant by this is that each of the surfaces 14, 16 are bent or otherwise curved in multiple directions, and, as shown, along two mutually perpendicular axis, namely along the length L and across the width W. Further, each surface may have more than one “bend” along its respective axis. For example, with particular reference to the embodiment shown, the body 12 has a form that approximates a side-oriented “S” shape along the length L. Other shapes, such as arc shaped bodies 12 are also contemplated. Such contouring allows each of the first and second surfaces 14, 16 to generally conform to complex external geometry of adjacent components—for example, the first surface 14 is shaped to conform to an external heat source whilst the second surface 16 is shaped to conform to a geometry of an external heat sink. In the illustrated embodiments, both the first and second surfaces 14, 16 have matching or complementary contouring, such that the body 12 has a substantially constant cross section. It is understood, however, that other embodiments may have first and second surfaces 14, 16 that are not parallel to one another. By way of a further example, it is also contemplated that only one of the first and second surfaces 14, 16 may be contoured, with the other being a substantially flat or planar plate.

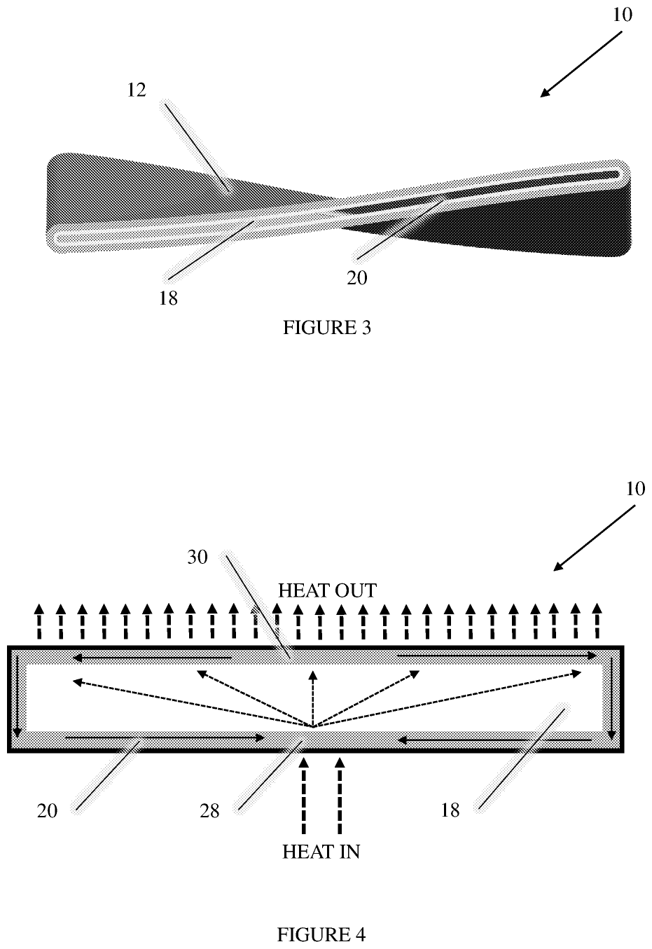

The space 18 will now be described with particular reference to FIG. 3. The space 18 extends substantially completely across a complete cross section of the body 12, with the body 12 thus being provided as a shell body. The space 18 provides a sealed chamber, within which working fluid of the heat spreader unit 10 is accommodated. The space 18 is preferably under vacuum. The vacuum within the space 18 promotes migration of the working fluid across the width T, from the first surface 14 to the second surface 16. As shown in FIG. 3, the space 18 is a substantially hollow space, largely devoid of internal structure. It is understood, however, that the space 18 may include a reinforcement element or structure 26. The reinforcement structure 26 may serve as a scaffold comprising a plurality of columns extending between and supporting the first and second surfaces 14, 16 in a spaced relationship. It is contemplated that the provision of such reinforcement structure 26 may increase a structural integrity of the body 12, allowing for said body 12 to be manufactured from comparatively lightweight materials. It is understood that notwithstanding the inclusion of a support structure, the space 18 is permeable to the migration of working fluid thereacross, between the first and second surfaces 14, 16. Further, the reinforcement structure 26 may itself be permeable to vaporous working fluid, having a porous structure.

A perimeter of the space 18 is at least partially defined by the porous member 20, which extends substantially therearound. The porous member 20 serves as a wick, providing the passageway for liquefied working fluid to be pumped under capillary action from the second surface 16 towards the first surface 14. The porous member 20 comprises an evaporator portion 28—disposed proximate the first surface 14—and a condenser portion 30—disposed proximate the second surface 16. Both the evaporator portion 28 and the condenser portion 30 of the porous member 20 are permeable to the working fluid. For example, the porous member 20 may include a plurality of microscopic apertures in the form of pores (not shown) through which the working fluid diffuses. The porous member 20 conforms to respective inner sides of the first and second surfaces 14, 16, being integrally formed therewith.

Notably, the porous member 20 may have a non-constant porosity along the passageway 20. What is meant by this is that the porosity of different sections of the passageway 20 to the working fluid can be “tuned” to ensure substantially even heat spread across the second surface 16. This allows the effective conductivity of the heat spreader 10 to be set or otherwise designed to maximize or otherwise meet specific heat dissipation requirements of a device to which the spreader 10 is to be installed. For example, should the body 12 have a non-constant thickness T, sections of the evaporator and/or condenser portions 28, 30 of the porous member 20 that correspond to higher thickness sections of the body 12 may have a higher porosity than sections of the porous member 20 corresponding to thinner sections of the body 12. In this way, a constant rate of heat transfer is promoted. This “tuning” of the porosity of the porous member 20 can be achieved, for example, by varying the density and size of the pores within the walls of the porous member 20. Alternatively/additionally, the internal geometry of the porous member 20 may vary along its length, such that the flow rate of the working fluid therein is variable. This variation in flow rate can also contribute to the rate at which the working fluid diffuses through the walls of the evaporator and/or condenser portions 28, 30 thereof.

Fluid flow of the working fluid within the heat spreader unit 10 and heat transfer facilitated thereby will now be described with reference to FIG. 4. Specifically, concentrated heat from an external heat source is absorbed (absorption represented in dashed arrow) through the first surface 14, which provides a base of the heat spreader unit 10. The heat source may, for example, be a processor chip or other adjacent electrical component that is of smaller size than the surface area of the first surface 14 in thermal communication therewith. The absorption of heat into the first surface 14 causes (liquid-phase, represented in solid arrow) working fluid in the evaporator portion 28 of the porous member 20 to evaporate into a vapour. The (vapour-phase, represented in dotted arrow) working fluid is then communicated through the walls of the porous member and into the space 18, where the working fluid migrates away from the heat source, and towards the (cooler) second surface 16. Proximate the second surface 16, the working fluid enters the condenser portion 30 of the porous member 20, releasing its latent heat in doing so (dissipation represented in dashed arrow). The latent heat is, in turn, absorbed into and dissipated across the second surface 16. The working fluid is then pumped along the passageway defined by the porous member 20 back towards the evaporator portion 28 thereof under capillary action. Accordingly, it is understood that the heat spreader unit 10 is a two-phase heat exchanger, with the space 18 and porous member 20 providing a closed loop system within which the working fluid serves as a heat transfer medium.

Whilst not limiting, it is envisaged that the heat spreader unit 10 as described herein is manufactured using an additive manufacturing process, with the body 12 and the porous member 20 being integrally formed with one another as a monolithic structure. It is envisaged that the heat spreader 10 is formed of a thermally conductive material. For example, the heat spreader is formed from a metallic material, such as steel, aluminum or titanium. Such example materials are known to be suitable for laser powder bed fusion processes.

Preferably, at least one of the first and second surfaces 14, 16 and the porous member 20 are formed simultaneously, with the walls of the porous member 20 forming an integral continuous join with an inner side of respective surface 14, 16. For example, the heat spreader 10 can be formed using a laser powder bed fusion metal additive manufacturing process. Advantageously, the heat spreader unit 10 when manufactured in accordance with such a method would not require separate assembly of the surfaces 14, 16, avoiding the need for separate and additional joining steps and the associated complexities and need for high tolerance manufacturing of the mating surfaces. Additionally, it is understood that the additive manufacturing process as described herein enables the porous member 20 to be formed such that it also conforms to the inner side of the first and/or second members 14, 16. Further, as the porous member 20 is formed simultaneously with said first and/or second member 14, 16, the porous member 20 is integrally connected thereto—with the integral connection providing a particularly robust and strong adherence that would not be possible through the use of conventional joining of separate components, reducing or substantially eliminating the possibility of the porous member 20 cracking or warping during manufacture/fabrication of the spreader unit 10. The resulting unit 10 is, accordingly, a seamless unitary component.

Furthermore, the complex geometries made possible through additive manufacturing of the porous member 20 enables the body 12 and porous member 20 therein to be formed with complex, conformal and/or tunable geometries. What is meant by this is that the exact geometry of these surface features can be altered to obtain specific characteristics, dependent on the heat dissipation requirements and footprint within which the heat spreader 10 is to be installed. For example, the first surface 14 may be formed to conform exactly to an external geometry of an adjacent heat source. Furthermore, additive manufacturing of the porous member 20 enables the porous member to be formed with a gradient or tunable conductivity, which is advantageous in optimizing the effectiveness of heat transfer from the first surface 14 to the second surface 16, increasing the effective thermal conductivity of the spreader 10.

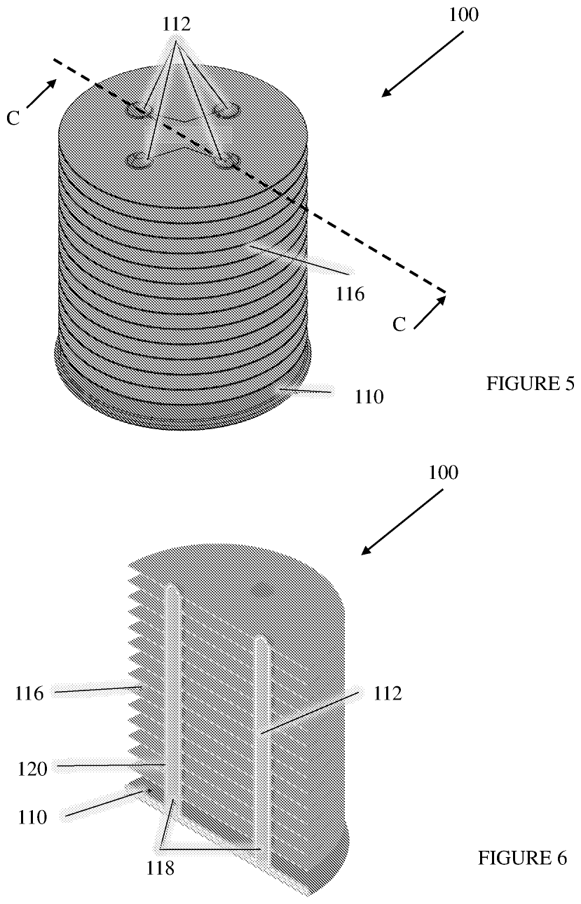

The heat spreader unit 10 may form part of a heat exchanger system 100. The heat exchanger system 100 will now be described with particular reference to FIGS. 5 to 8.

The heat exchanger 100 comprises a base 110 and a plurality of fins 116 that are in thermal communication therewith. The heat exchanger is an integrated heat exchanger, with the base 110 and fins 116 being formed as a unitary component. The base 110 is provided as a vapour chamber, formed in accordance with the heat spreader 10 as described herein. As shown, each of the base 110 and the fins 116 are disc shaped. It is understood, however, that other geometries are also contemplated, depending on the footprint within which the heat exchanger 100 is to be installed. The fins 116 are formed as monolithic solids and are provided in a stack, with each disc-shaped fin 116 being arranged substantially parallel to one another and to the base 110. Together, the fins form a heat sink, with a comparatively large surface area for dissipating heat from the base 110 to atmosphere. Preferably, each fin 116 is formed from a highly conductive material. Examples of metallic materials include copper and aluminum.

At least one heat transfer member 112 is provided to transfer heat between the base 110 and the fins 116. Each heat transfer member 112 extends substantially perpendicular from the base 110 through each of the fins 116, forming an integral join therewith. In operation, the heat transfer member 112 communicates heat from the base 110 to the fins 116. In the illustrated embodiment, there are four heat transfer members 112, each extending from the base 110. It is understood, however, that depending on heat dissipation requirements that there could be more or less. The heat transfer members 112 are provided in the form of heat pipes, having a substantially tubular shape. Each transfer member includes an internal chamber 118 within which working fluid is contained, and a porous wicking element 120 that extends around a perimeter thereof, proximate the gas tight outer walls of the transfer member 112.

Best shown in FIGS. 6, the internal chamber 116 of each of the heat transfer members 114 is in fluid communication with the interior space 18 of the base 110. Further, the porous wicking element 120 of the transfer member is fluidly connected to the porous member 20 of the base 110. Accordingly, it is understood that there is a direct flow of working fluid between the base 110 and the heat transfer members 114, with the fins 116, in effect, providing the dissipation surface across which heat from the base 110 is spread.

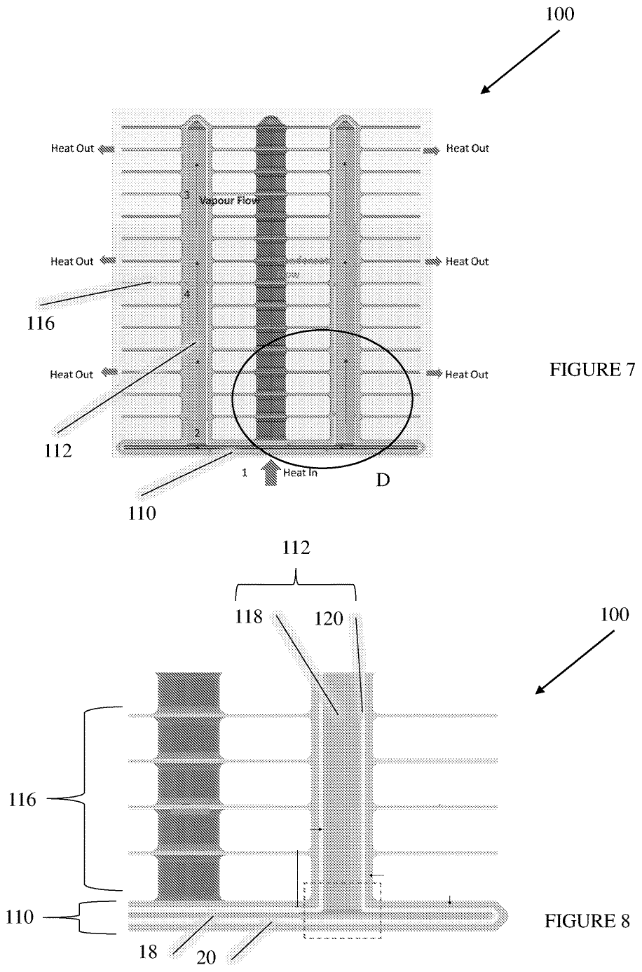

Heat transfer between the base 110 and the fins 116 will now be described with reference to FIGS. 7 and 8. Specifically it is understood that the application of a concentrated/high flux heat to the base 110 results in the heat being absorbed by the base 110, leading to an evaporation of working fluid within the porous member 20 thereof. The vapourised working fluid diffuses into the interior space 18 of the base 110, and migrates across the space, towards cooler regions thereof. In particular, the vapourised working fluid within the space 18 is communicated away from the heat source and towards the fins 116, via the internal chamber 118 of the respective heat transfer members 114. As working fluid reaches the “cool side” of the internal periphery of the chambers 118, it condenses into the wicking element 120 thereof, dissipating its latent heat across the adjoining fins 116. The liquefied working fluid it then returned to the base 110 under capillary action, with the wicking element 120 and the porous member 20 interfacing together to provide a continuous passageway. This hydraulic connection (represented by the dashed box in FIG. 8) between the chamber 118 of the transfer members 114 and the space 18 of the base 110 allows the working fluid to travel throughout the entire structure of the heat exchanger 100, increasing the effective conductivity and heat dissipation performance thereof.

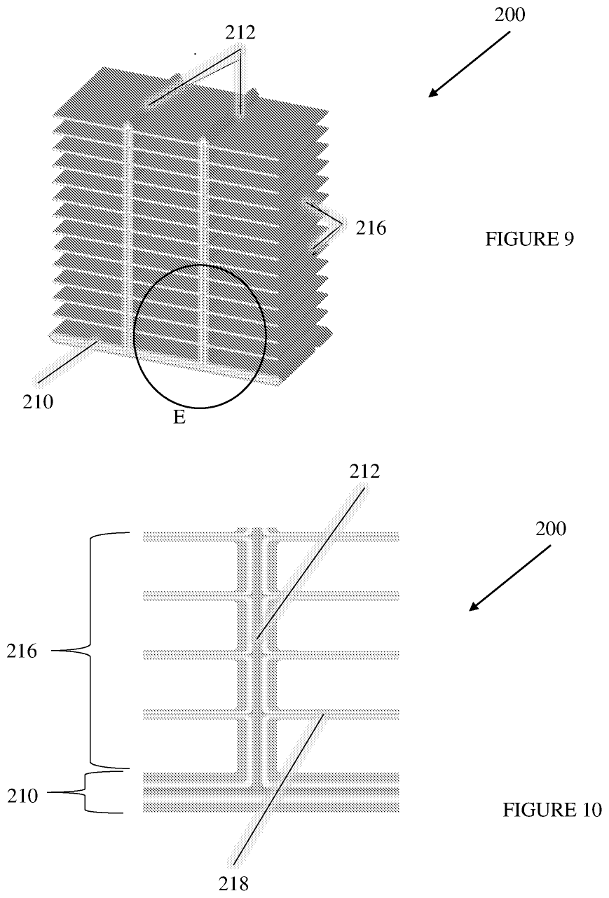

The heat spreader unit 10 may, in an alternative embodiment of the invention, form part of a heat exchanger system 200. The heat exchanger system 200 will now be described with particular reference to FIGS. 9 and 10. For clarity, similar components and functional analogues will be described using similar terminology and numerical references.

The heat exchanger 200 comprises a base 210 and a plurality of fins 216 that are in thermal communication therewith. The base 210 is provided as a vapour chamber, formed in accordance with the heat spreader 10 as described herein. As shown, each of the base 210 and the fins 216 are rectangular shaped. It is understood, however, that other geometries are also contemplated, depending on the footprint within which the heat exchanger 200 is to be installed. The fins 216 are provided in a stack, substantially parallel to one another and to the base 110. Together, the fins 216 form a heat sink, with a comparatively large surface area for dissipating heat from the base 210 to atmosphere.

Each fin 216 is thermally and fluidly connected to the base 210 via at least one heat transfer member 212. Each heat transfer member 212 extends substantially perpendicular from the base 210 through each of the fins 216, forming an integral join therewith. As shown, there are two heat transfer members 212, each extending substantially vertically from the horizontal base 210. It is understood, however, that depending on heat dissipation requirements the density of the heat transfer members 212 (and, for that matter, fins 216) can be increased or decreased. In contrast to heat exchanger 210, each of the heat transfer members 212 is provided in the form of a vapour chamber, in accordance with the heat spreader 10 described herein. It is contemplated that the use of a vapour chamber as a heat transfer member (as opposed to the use of a heat pipe) may improve the effective conductivity and heat dissipation performance of the heat exchanger 200.

In contrast to the solid fins 116 of heat exchanger 100, the fins 216 as shown are formed as phase change fins. What is meant by this is that each fin 216 may be formed as a hollow fin, in accordance with the heat spreader 10 described herein. It is understood, however, that the fins 216 of heat exchanger 200 could, alternatively, be replaced by solid fins 116. Likewise, it is also contemplated that the solid fins 116 of heat exchanger 100 could, alternatively, be replaced hollow fins 216, depending on operational requirements.

Best shown in FIG. 10, each fin 216 is provided as a hollow body, having an internal cavity 218 within which working fluid is contained, and a porous wicking component 220 that extends around a perimeter thereof, proximate the gas tight outer walls of each fin 216. The cavity 218 of each fin 216 is thermally and fluidly connected to the respective inner chamber and space of the heat transfer member 212 and base 210. Likewise, the wicking component 220 of each fin 220 is fluidly connected to the respective wicking element and porous member of the heat transfer member 212 and base 210, interfacing directly therewith. In this way, the fins 216 have a particularly high thermal conductivity, due to the phase change heat transfer occurring with them. It is thought that such an arrangement would not be possible through conventional, subtractive, manufacturing techniques (i.e. non additive manufacturing) due the precision and high tolerance required to interface together the respective inner space/chamber/cavities and porous member/element/component of the base 210, heat transfer member 212 and fins 216.

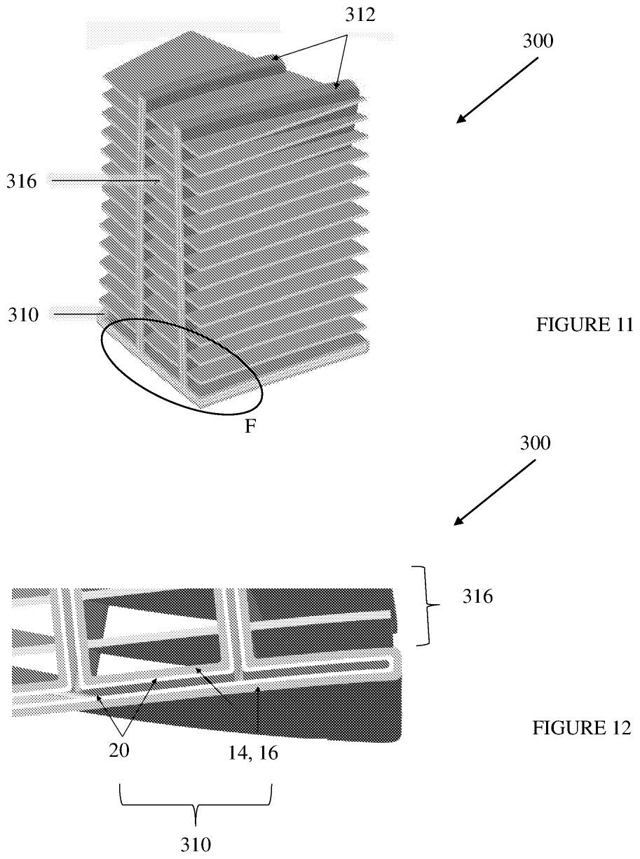

Whilst the illustrated embodiments of heat exchangers 100, 200 include substantially planar bases 110, 210 respectively, it is understood that the bases may, alternatively, be conformal bases. A heat exchanger system 300—which includes a conformal base 310—will now be described with particular reference to FIGS. 11 and 12. Once more, for clarity, similar components and functional analogues will be described using similar terminology and numerical references.

The heat exchanger 300 comprises a conformal base 310 and a plurality of fins 316 that are in thermal communication therewith. As shown, each of the base 210 and the fins 316 have a contoured rectangular shape, exhibiting surface curvature in multiple directions, in particular along a length and across a width thereof. It is understood, however, that other geometries are also contemplated, depending on the footprint within which the heat exchanger 300 is to be installed. The fins 316 are provided in a stack, substantially parallel to one another and to the base 310. Together, the fins 316 form a heat sink, with a comparatively large surface area for dissipating heat from the base 310 to atmosphere. As shown, each fin 316 is provided as a solid fin, similar to the fins 116 of heat exchanger 100. It is understood, however, that the fins 316 may, alternatively, be provided as phase change fins similar to fins 216 of heat exchanger 100.

Each fin 316 is thermally and fluidly connected to the base 210 via at least one heat transfer member 312. As illustrated, the heat transfer member 312 protrudes outwardly from the base 310 through each of the fins 316, forming an integral join therewith. As shown, there are two heat transfer members 312, each protruding in a substantially vertically direction from the substantially horizontal base 310. It is understood, however, that depending on heat dissipation requirements the density of the heat transfer members 312 (and, for that matter, fins 316) can be increased or decreased. The heat transfer members 312 is provided in the form of a conformal vapour chamber, in accordance with the heat spreader 10 described herein. It is thought that the use of a conformal vapour chamber as a heat transfer member 312 may make heat exchanger 300 particularly suitable for uses in electrical devices that demand high heat dissipation performance within a compact overall footprint or confined internal space. In other embodiments, it is also contemplated that the heat transfer member 312 may be replaced by a substantially tubular heat pipe, similar to the heat transfer member 112 of heat exchanger 100.

Summarily, it is to be understood that the heat spreader unit 10 and heat exchange systems 100, 200 and 300 as described herein provides several performance advantages and manufacturability improvements over typical, existing heat spreaders and heat exchangers. For example, the heat spreader may be particularly suitable for use in electronic devices, operable to spread heat from small heat sources (for example ICs) to larger heat sinks and to form part of an engineered thermal management solution required to manage the heat load of the electronic device. In particular, in situations where space is constrained, providing a conformal heat spreader—i.e. with contoured evaporator and condenser surfaces—may be particularly useful where limited internal geometry requirements of the electrical device dictate that complex shapes are required. Finally, the provision of an integrated heat exchanger is particularly as a thermal management solution which combines the effectiveness of two-phase heat transfer in both the heat spreader (base) and heat sink (fins). Such improved heat dissipation performance may be particularly advantageous for high power electronic devices which demand more complex and effective thermal management solutions.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavor to which this specification relates.

Throughout this specification and the claims which follow, unless the context requires otherwise, the word ‘comprise’, and variations such as ‘comprises’ and ‘comprising’, will be understood to imply the inclusion of a stated integer or step or group of integers or steps but not the exclusion of any other integer or step or group of integers or steps.

### LEGEND

| | |
|---|---|
| 10 | Heat Spreader Unit |
| 12 | Body |
| 14 | First Surface |
| 16 | Second Surface |
| 18 | Space |
| 20 | Porous Member |
| 22 | End Walls |
| 24 | Side Walls |
| 26 | Reinforcement Structure |
| 28 | Evaporator Portion |
| 30 | Condenser Portion |
| 100 | Heat Exchanger System |
| 110 | Base |
| 112 | Heat Transfer Member |
| 116 | Fins |
| 118 | Internal Chamber |
| 120 | Wicking Element |
| 200 | Heat Exchanger System |
| 210 | Base |
| 212 | Heat Transfer Member |
| 216 | Fins |
| 218 | Cavity |
| 220 | Wicking Component |
| 300 | Heat Exchanger System |
| 310 | Base |
| 312 | Heat Transfer Member |
| 316 | Fins |

1. A heat spreader, comprising: a body having a first surface, a second surface and an interior space therebetween, with heat being transferred from the first surface to the second surface by migration of vapourised working fluid through the space; and a porous member that is integrally formed with the body that extends around the space and provides a passageway for returning condensed working fluid towards the first surface.

2. The heat spreader of claim 1, wherein the body is a plate body having a substantially constant cross section, with heat being transferred across a thickness thereof between the first and second surfaces.

3. The heat spreader of claim 1, wherein the first surface is shaped to conform to an external geometry of a heat source.

4. The heat spreader of claim 3, wherein the first surface is curved across each of a length and width thereof.

5. The heat spreader of claim 1, wherein the second surface is shaped to conform to an external geometry of a heat sink.

6. The heat spreader of claim 5, wherein the second surface is curved across each of a length and width thereof.

7. The heat spreader of claim 1, wherein the space is under vacuum.

8. The heat spreader of claim 1, wherein a reinforcement structure is provided within the space that supports the first and second surfaces in a spaced relationship, wherein the reinforcement structure is integrally formed with the body.

9. The heat spreader of claim 1, wherein a porosity of the porous member is tunable in accordance with heat dissipation requirements of the heat spreader.

10. The heat spreader of claim 9, wherein the porosity of the porous member varies along a length of the passageway.

11. A method of manufacturing the heat spreader of claim 1, the method including simultaneously forming the body and the porous member through an additive manufacturing process.

12. A heat exchanger comprising a base and a plurality of fins in thermal communication therewith, wherein the base is provided in the form of the heat spreader of claim 1.

13. The heat exchanger of claim 12, wherein the plurality of fins are integrally formed with the base.

14. The heat exchanger of claim 12, wherein the plurality of fins are provided in a stacked arrangement, with each fin extending substantially parallel to the base.

15. The heat exchanger of claim 12, further comprising at least one heat transfer member integrally formed with the base that is configured to communicate heat from the base to the plurality of fins.

16. The heat exchanger of claim 15, wherein the heat transfer member extends substantially perpendicular to the base through the plurality of fins to thereby distribute heat substantially evenly thereacross.

17. The heat exchanger of claim 15, wherein the heat transfer member is formed in accordance with the heat spreader of claim 1.

18. The heat exchanger of claim 17, wherein the space and porous member of the heat transfer member are in fluid communication, respectively, with the space and porous member of the base.

19. The heat exchanger of claim 12, wherein each of the plurality of fins is a hollow fin that is formed in accordance with the heat spreader of claim 1.

20. The heat exchanger of claim 19, wherein the space and porous member of each of the plurality of fins are in fluid communication, respectively, with the space and porous member of the base.
